(19) United States
(12) Patent Application Publication
(10) Pub. No.: US 2025/0194375 A1
(43) Pub. Date: Jun. 12, 2025

(54) ELECTRONIC DEVICE COMPRISING DISPLAY PANEL POSITIONED ON CAMERA

(71) Applicant: Samsung Electronics Co., Ltd., Suwon-si (KR)

(72) Inventors: Minsuk UHM, Suwon-si (KR); Sungyoung SHIN, Suwon-si (KR); Dongseop LEE, Suwon-si (KR); Haechang LEE, Suwon-si (KR); Kwangtai KIM, Suwon-si (KR); Donghyun YEOM, Suwon-si (KR)

(21) Appl. No.: 19/054,027

(22) Filed: Feb. 14, 2025

Related U.S. Application Data
(63) Continuation of application No. PCT/KR2023/013032, filed on Aug. 31, 2023.

(30) Foreign Application Priority Data
Sep. 22, 2022 (KR) 10-2022-0120353
Oct. 19, 2022 (KR) 10-2022-0135279

(51) Int. Cl. H10K 59/65; H10K 59/121; H10K 59/122

(52) U.S. Cl. CPC H10K 59/65; H10K 59/121; H10K 59/122

(57) ABSTRACT

An electronic device is provided. The electronic device includes a camera, a display panel including a first region disposed on the camera and a second region surrounding at least a portion of the first region, wherein the first region includes an emission layer including a plurality of pixels uniformly spaced apart from each other, an encapsulation layer on the emission layer, and an opaque metal layer below the emission layer, wherein the opaque metal layer includes a plurality of openings disposed between the plurality of pixels, wherein each of the plurality of openings includes a periphery including first portions, each having a first radius of curvature, spaced apart from each other, and second portions, each having a second radius of curvature shorter than the first radius of curvature, positioned between the first portions of the periphery, and wherein each of the first portions of the periphery faces each of pixels positioned along the periphery.

### CROSS-REFERENCE TO RELATED APPLICATION(S)

This application is a continuation application, claiming priority under § 365(c), of an International application No. PCT/KR2023/013032, filed on Aug. 31, 2023, which is based on and claims the benefit of a Korean patent application number 10-2022-0120353, filed on Sep. 22, 2022, in the Korean Intellectual Property Office, and of a Korean application number 10-2022-0135279, filed on Oct. 19, 2022, the disclosure of each of which is incorporated by reference herein in its entirety.

### BACKGROUND

### 1. Field

The disclosure relates to an electronic device including a display panel positioned on a camera.

### 2. Description of Related Art

An electronic device may include a display panel. The display panel may provide a display area. For the display area having a larger size, an electronic device including an optical sensor disposed below the display panel is being developed. For example, the optical sensor may include a camera.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device comprising display panel positioned on camera.

Additional aspects will be set forth in part in the description which follows and, in part, will be apparent from the description, or may be learned by practice of the presented embodiments.

In accordance with an aspect of the disclosure, an electronic device is provided. The electronic device includes a camera, a display panel including a first region disposed on the camera, and a second region surrounding at least a portion of the first region, wherein the first region includes an emission layer including a plurality of pixels uniformly spaced apart from each other, an encapsulation layer on the emission layer, and an opaque metal layer below the emission layer, wherein the opaque metal layer includes a plurality of openings disposed between the plurality of pixels when viewed along the first region in a first direction opposite to a second direction in which the display panel faces, wherein each of the plurality of openings includes a periphery including first portions, each having a first radius of curvature, spaced apart from each other when viewed along the first region in the first direction, and second portions, each having a second radius of curvature shorter than the first radius of curvature, positioned between the first portions of the periphery, and each of the first portions faces each of pixels positioned along the periphery.

In accordance with another aspect of the disclosure, a display panel is provided. The display panel includes a first region disposed on a camera, and a second region surrounding at least a portion of the first region wherein the first region includes an emission layer including a plurality of pixels uniformly spaced apart from each other, an encapsulation layer on the emission layer, and an opaque metal layer below the emission layer, wherein the opaque metal layer includes a plurality of openings disposed between the plurality of pixels when viewed along the first region in a first direction opposite to a second direction in which the display panel faces, wherein each of the plurality of openings includes a periphery including first portions, each having a first radius of curvature, spaced apart from each other when viewed along the first region in the first direction, and second portions, each having a second radius of curvature shorter than the first radius of curvature, positioned between the first portions of the periphery, and wherein each of the first portions faces each of pixels positioned along the periphery.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a plan view of an electronic device according to an embodiment of the disclosure;

FIG. 2 illustrates an enlarged view of a region 120 of FIG. 1 according to an embodiment of the disclosure;

FIG. 3 is a cross-sectional view cut along line A-A′ of FIG. 2 according to an embodiment of the disclosure;

FIG. 4 illustrates an example of an opaque metal layer in a display panel according to an embodiment of the disclosure;

FIG. 5 illustrates a state of light passing through an opening in an opaque metal layer according to an embodiment of the disclosure;

FIG. 6 illustrates a quality of an image obtained through a camera positioned below an opaque metal layer according to an embodiment of the disclosure;

FIG. 7 illustrates another example of an opaque metal layer in a display panel according to an embodiment of the disclosure;

FIG. 8 is a block diagram of an electronic device in a network environment according to an embodiment of the disclosure; and

FIG. 9 is a block diagram of a display module according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

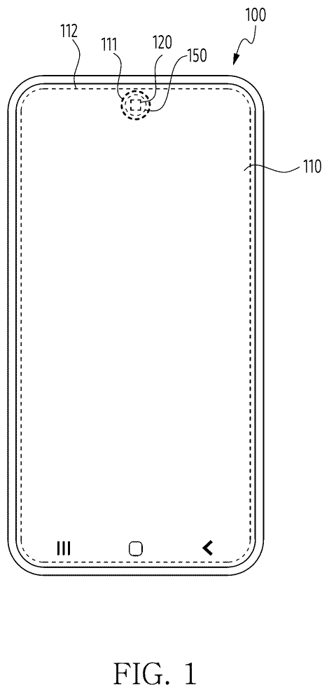

FIG. 1 illustrates a plan view of an electronic device according to an embodiment of the disclosure.

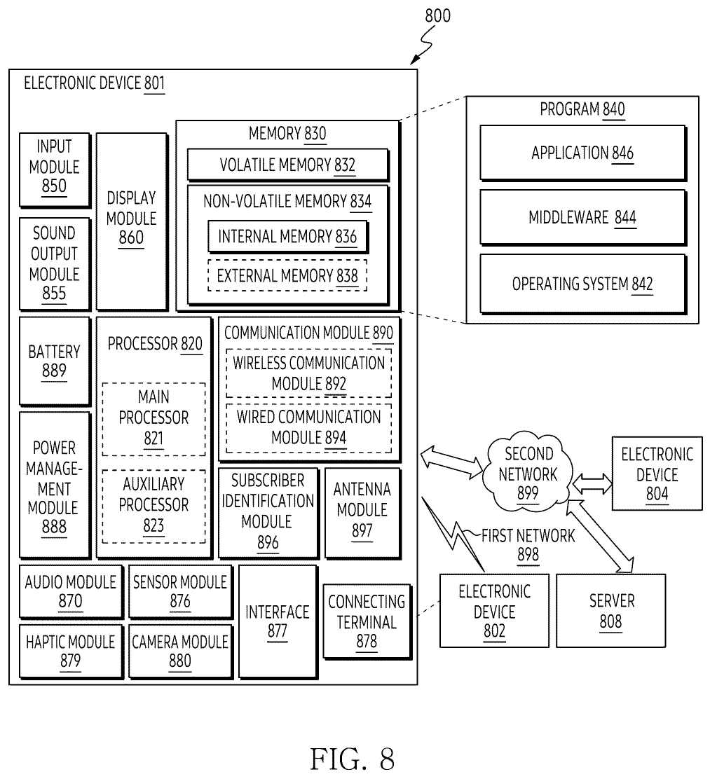

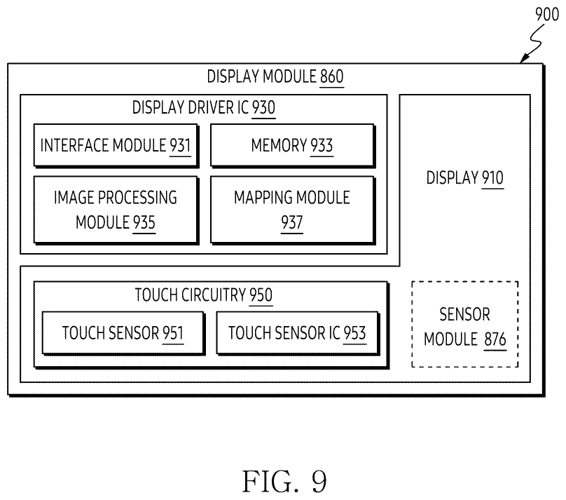

Referring to FIG. 1, an electronic device 100 (e.g., an electronic device 801 of FIG. 8) may include a display panel 110 (e.g., a display 910 of FIG. 9) and a camera 150 (e.g., a camera module 880 of FIG. 8).

For example, the display panel 110 may include a first region 111 positioned on the camera 150 and a second region 112 surrounding at least a portion of the first region 111. FIG. 1 illustrates an example in which a size of the first region 111 is larger than a size of the camera 150 when the display panel 110 is viewed in a first direction opposite to a second direction in which the display panel 110 faces, but it is not limited thereto. For example, when the display panel 110 is viewed in the first direction, the size of the first region 111 may be the same as the size of the camera 150 or may be smaller than the size of the camera 150.

For example, a structure of the first region 111 may be different from a structure of the second region 112 for a path of light to the camera 150 positioned below the first region 111.

For example, a spacing between a plurality of pixels uniformly spaced apart from each other in the first region 111 may be wider than a spacing between a plurality of other pixels uniformly spaced apart from each other in the second region 112, for the path of light to the camera positioned below the first region 111. For example, the plurality of pixels may be arranged sparsely, unlike the plurality of other pixels that are arranged densely. For example, the number of pixels positioned per unit area in the first region 111 may be smaller than the number of pixels located per unit area in the second region 112.

For example, each of the plurality of pixels and each of the plurality of other pixels may include sub-pixels, respectively. For example, the sub-pixels may include at least one first sub-pixel for emitting light having a first color (e.g., red), at least one second sub-pixel for emitting light having a second color (e.g., blue), and at least one third sub-pixel for emitting light having a third color (e.g., green).

For example, unlike the second region 112, the first region 111 may include an opaque metal layer (not illustrated in FIG. 1) for a path of light to the camera 150 positioned below the first region 111. For example, the opaque metal layer may be included in the first region 111 to reduce diffraction of light caused by the plurality of pixels and a plurality of electrical wires for driving the plurality of pixels being applied to the camera 150. For example, the opaque metal layer may include a plurality of openings to increase the amount (or intensity) of light reaching the camera 150.

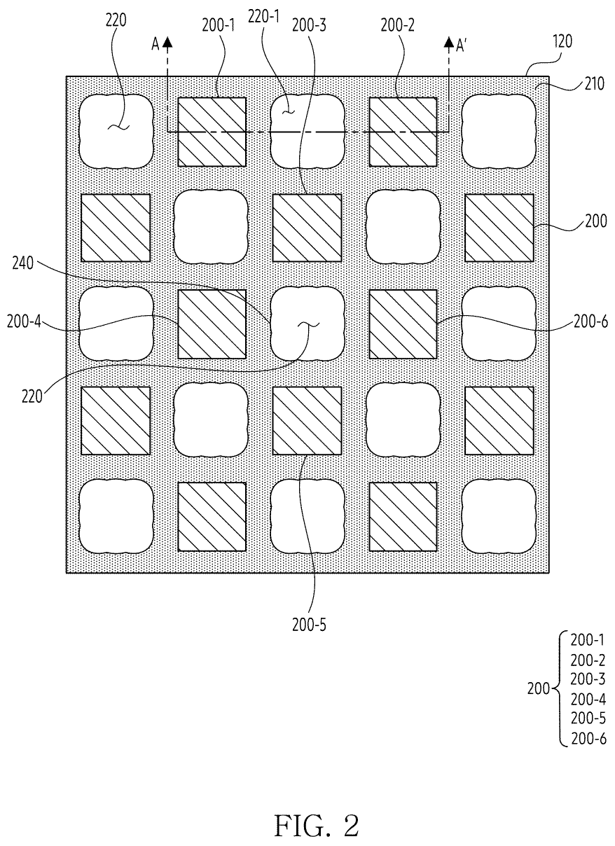

For example, a region 120 in the first region 111 may include a portion of the plurality of pixels and a portion of the opaque metal layer. The portion of the plurality of pixels and the portion of the opaque metal layer, which are included in the region 120, may be exemplified through FIG. 2.

FIG. 2 illustrates an enlarged view of the region 120 of FIG. 1 according to an embodiment of the disclosure.

Referring to FIG. 2, the region 120 may include a plurality of pixels 200 uniformly spaced apart from each other and an opaque metal layer 210 positioned below the plurality of pixels 200. For example, the opaque metal layer 210 may include a plurality of openings 220 positioned between the plurality of pixels 200 when the first region 111 is viewed in the first direction. For example, each of the plurality of openings 220 may be partially surrounded by pixels. For example, the pixels (e.g., pixel 200-3, pixel 200-4, pixel 200-5, and pixel 200-6) may be positioned along a periphery 240 of each of the plurality of openings 220.

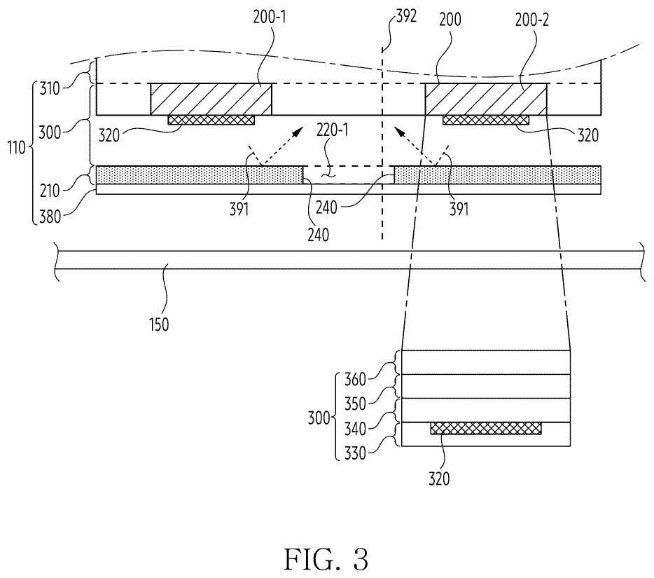

For example, the opaque metal layer 210 may be positioned below an emission layer including a plurality of pixels 200 uniformly spaced apart from each other. The opaque metal layer 210 positioned below the emission layer may be exemplified through FIG. 3.

FIG. 3 is a cross-sectional view cut along line A-A′ of FIG. 2 according to an embodiment of the disclosure.

Referring to FIG. 3, a first region 111 of a display panel 110 may include an emission layer 300 including a plurality of pixels 200 (e.g., pixel 200-1 and pixel 200-2), an encapsulation layer 310 on the emission layer 300, an opaque metal layer 210 positioned below the emission layer 300, and a substrate 380. For example, the emission layer 300, the encapsulation layer 310, the opaque metal layer 210, and the substrate 380 may be positioned on or above the camera 150.

For example, the emission layer 300 may include a substrate 330 (i.e., circuit layer) including a thin film transistor (TFT) 320. For example, the TFT 320 may include low temperature polycrystalline silicon (LTPS) or low temperature polycrystalline oxide (LTPO). However, it is not limited thereto. For example, the TFT 320 may be disposed to drive each of sub-pixels (e.g., a sub-pixel for red light emission, a sub-pixel for blue light emission, and/or a sub-pixel for green light emission) in the pixels 200. For example, the TFT 320 may be positioned below each of the sub-pixels. For example, a single TFT 320 may be allocated for one sub-pixel. For another example, the single TFT 320 may be disposed to drive at least a portion of the sub-pixels. For example, the TFT 320 may be allocated for two or more sub-pixels.

For example, the emission layer 300 may include a layer 340 including a first electrode (e.g., anode) positioned on the substrate 330.

For example, the emission layer 300 may include a layer 350, including an organic emitting material, positioned on the layer 340. For example, the layer 350 may cover the first electrode printed in the layer 340. Although not illustrated in FIG. 3, a pixel definition layer (PDL) may be partially interposed between the layer 340 and the layer 350. For example, the PDL may be positioned along a periphery of each of a plurality of pixels 200 (e.g., pixel 200-1 and pixel 200-2), or may be positioned along a periphery of each of sub-pixels in each of the plurality of pixels 200.

For example, the emission layer 300 may include a layer 360 including a second electrode (e.g., cathode) positioned on the layer 350. For example, since the organic emitting material is included in the layer 350 interposed between the layer 340 and the layer 360, the organic emitting material may emit light based on an electric field (or electromagnetic field) formed between the anode in the layer 340 and the cathode in the layer 360. For example, the electric field may be formed through the TFT 320.

For example, the encapsulation layer 310 may be disposed on the layer 360. For example, the encapsulation layer 310 may cover the layer 360 to reduce moisture or air from entering the display panel 110 (or the emission layer 300). For example, the encapsulation layer 310 may include at least one inorganic layer and at least one organic layer. For example, the at least one inorganic layer and the at least one organic layer may be alternately stacked within the first encapsulation layer 310.

Although not illustrated in FIG. 3, the first region 111 of the display panel 110 may further include at least one layer on the encapsulation layer 310. For example, the at least one layer may include a functional layer. For example, the functional layer may include a polymer material. For example, the functional layer may include a plurality of members. However, it is not limited thereto.

Although not illustrated in FIG. 3, the first region 111 of the display panel 110 may further include a plurality of electrical wires for driving a plurality of pixels 200 (e.g., pixel 200-1 and pixel 200-2). For example, the plurality of electrical wires may be connected with the TFT 320.

For example, the opaque metal layer 210 may be positioned below the emission layer 300 to reduce light 391 diffracted by at least a portion of the plurality of electrical wires and at least a portion of the plurality of pixels 200 from being received to the camera 150. For example, the opaque metal layer 210 may be positioned on the substrate 380 or may be contacted on the substrate 380. For example, the substrate 380 may include a bendable material such as polyimide (PI). For example, the opaque metal layer 210 may include a plurality of openings 220 (e.g., opening 220-1) for light 392 received directly from the outside to the camera 150. For example, the light 392 may indicate light received to the camera 150 without passing through the plurality of pixels 200 and the plurality of electrical wires. For example, each of the plurality of openings 220 (e.g., opening 220-1) may be positioned between a plurality of pixels 200 (e.g., pixel 200-1 and pixel 200-2).

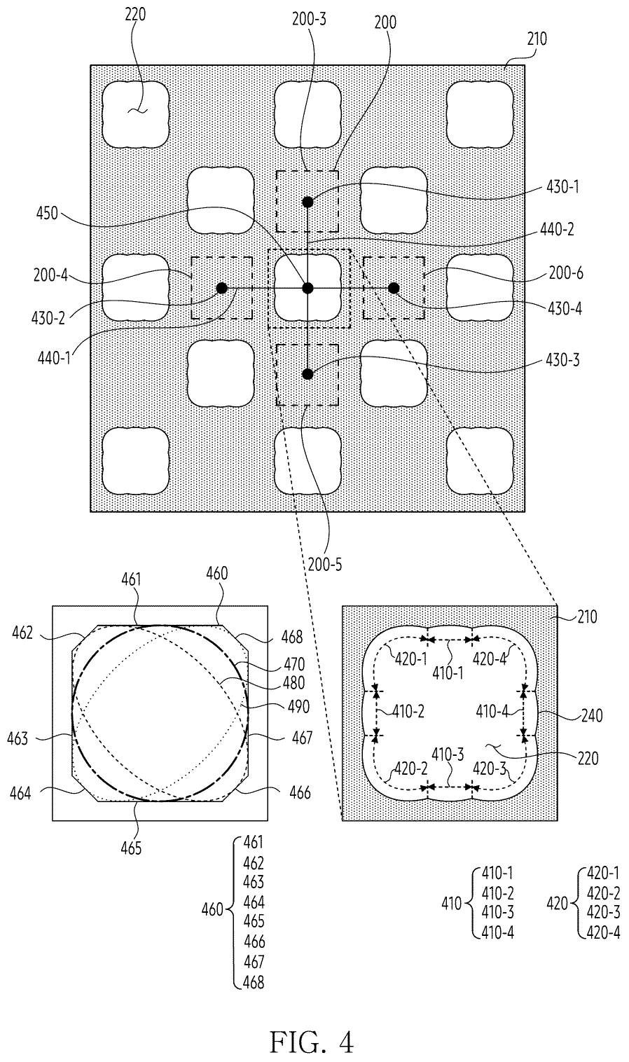

For example, the light 392 may be received to the camera 150 through each of the plurality of openings 220. For example, the light 392 received to the camera 150 may be diffracted or diffused by each of the plurality of openings 220. For example, a periphery 240 of each of the plurality of openings 220 may have a shape for reducing the diffraction (or diffusion). The shape of the periphery 240 may be exemplified through FIG. 4.

FIG. 4 illustrates an example of an opaque metal layer in a display panel according to an embodiment of the disclosure.

Referring to FIG. 4, each of a plurality of openings 220 in an opaque metal layer 210 may include a periphery 240.

For example, the periphery 240 may include first portions 410 having a first radius of curvature. For example, the first portions 410 may include a portion 410-1, a portion 410-2, a portion 410-3, and a portion 410-4. For example, the first portions 410 may be spaced apart from each other. For example, the portion 410-1 may be spaced apart from each of the portion 410-2, the portion 410-3, and the portion 410-4, respectively. For example, the portion 410-2 may be spaced apart from each of the portion 410-3 and the portion 410-4. For example, the portion 410-3 may be spaced apart from the portion 410-4.

For example, the periphery 240 may include second portions 420 having a second radius of curvature smaller than the first radius of curvature. For example, the second portions 420 may include a portion 420-1, a portion 420-2, a portion 420-3, and a portion 420-4. For example, the second portions 420 may be spaced apart from each other. For example, the portion 420-1 may be spaced apart from each of the portion 420-2, the portion 420-3, and the portion 420-4. For example, the portion 420-2 may be spaced apart from each of the portion 420-3 and the portion 420-4. For example, the portion 420-3 may be spaced apart from the portion 420-4.

For example, each of the second portions 420 may be positioned between the first portions 410. For example, the portion 420-1 may be positioned between the portion 410-1 and the portion 410-2. For example, the portion 420-1 may connect the portion 410-1 to the portion 410-2. For example, the portion 420-2 may be positioned between the portion 410-2 and the portion 410-3. For example, the portion 420-2 may connect the portion 410-2 and the portion 410-3. For example, the portion 420-3 may be positioned between the portion 410-3 and the portion 410-4. For example, the portion 420-3 may connect the portion 410-3 and the portion 410-4. For example, the portion 420-4 may be positioned between the portion 410-1 and the portion 410-4. For example, the portion 420-4 may connect the portion 410-1 to the portion 410-4.

For example, unlike the second portions 420, the first portions 410 may face each of pixels (e.g., pixel 200-3, pixel 200-4, pixel 200-5, and pixel 200-6) positioned along the periphery 240. For example, the fact that each of the first portions 410 faces the pixels may indicate that a position at which a distance from each point indicating respectively positions of the pixels to the periphery 240 is minimum is included in each of the first portions 410. For example, since a position where a distance from a point 430-1 indicating a position of the pixel 200-3 to the periphery 240 is minimum is within the portion 410-1, the portion 410-1 may face the pixel 200-3. For example, since a position where a distance from a point 430-2 indicating a position of the pixel 200-4 to the periphery 240 is minimum is within the portion 410-2, the portion 410-2 may face the pixel 200-4. For example, since a position where a distance from a point 430-3 indicating a position of the pixel 200-5 to the periphery 240 is minimum is within the portion 410-3, the portion 410-3 may face the pixel 200-5. For example, since a position where a distance from a point 430-4 indicating a position of the pixel 200-6 to the periphery 240 is minimum is within the portion 410-4, the portion 410-4 may face the pixel 200-6.

For example, the first portions 410 may be a portion of a circle (e.g., circle 470). For example, the pixels (e.g., pixel 200-3, pixel 200-4, pixel 200-5, and pixel 200-6) positioned along the periphery 240 may include first pixels (e.g., pixel 200-4, and pixel 200-6) on substantially the same row and second pixels (e.g., pixel 200-3 and pixel 200-5) on substantially the same column. For example, a center of the circle may be positioned on an intersection point 450 of a first line 440-1 connecting points (e.g., point 430-2 and point 430-4) indicating positions of the first pixels and a second line 440-connecting points (e.g., point 430-1 and point 430-3) indicating positions of the second pixels. However, it is not limited thereto.

For example, a portion (e.g., portion 420-1 and portion 420-3) of the second portions 420 may be a portion of an ellipse (e.g., ellipse 480). For example, a remaining (or another) portion (e.g., portion 420-2 and portion 420-4) of the second portions 420 may be a portion of another ellipse (e.g., ellipse 490). For example, a major axis of the ellipse and the major axis of the other ellipse may intersect with each other. For example, the major axis of the ellipse and the major axis of the other ellipse may intersect with each other at the intersection point 450. For example, the major axis of the ellipse and the major axis of the other ellipse may be substantially perpendicular.

For example, the periphery 240 may include a portion of the circle that is the first portions 410, a portion of the ellipse that is the portion of the second portions 420, and a portion of the other ellipse that is the remaining portion of the second portions 420.

For example, the circle may be contacted with a portion of sides of an imaginary octagon, the ellipse may be contacted with another portion of the sides of the imaginary octagon, and the other ellipse may be contacted with a remaining portion of the sides of the imaginary octagon.

For example, when each of a plurality of openings 220 is formed at a maximum size in order to reduce light (e.g., light 391) diffracted by at least a portion of the plurality of pixels 200 and at least a portion of the plurality of electrical wires from being received to the camera 150 and increase light (e.g. light 392) received directly from the outside to the camera 150, a shape of the periphery 240 of each of the plurality of openings 220 may be an octagon 460. For example, since each side of the octagon 460 is straight line, light passing through each of the plurality of openings 220 including the periphery 240 in the shape of the octagon 460 may be diffracted or diffused. The periphery 240 may include curved portions (e.g., first portions 410 and second portions 420) having a size similar to that of the octagon 460 to reduce the diffraction or diffusion of the light.

The octagon 460 may include sides 461 to 468. For example, a length of each of side 461, side 463, side 465, and side 467 may be longer than a length of each of side 462, side 464, side 466, and side 468. For example, the side 461 may be parallel to the side 465, the side 462 may be parallel to the side 466, the side 463 may be parallel to the side 467, and the side 464 may be parallel to the side 468. For example, each of the side 461 and the side 465 may be perpendicular to each of the side 463 and the side 467, and each of the side 462 and the side 466 may be perpendicular to each of the side 464 and the side 468. However, it is not limited thereto.

For example, the first portions 410 may be a portion of the circle 470 contacted with all of the side 461, the side 463, the side 465, and the side 467. For example, a portion (e.g., portion 420-1 and portion 420-3) of the second portions 420 may be a portion of the ellipse 480 contacted with all of the side 462 and the side 466. For example, a remaining portion (e.g., portion 420-2 and portion 420-4) of the second portions 420 may be a portion of the ellipse 490 contacted with all of the side 464 and the side 468. For example, the periphery 240 may be formed based on connecting the portion (e.g., first portions 410) of the circle 470, the portion (e.g., the portion of the second portions 420) of the ellipse 480, and the portion (the remaining portion of the second portions 420) of the ellipse 490, which are positioned at the outermost portion to have the most similar size to the octagon 460.

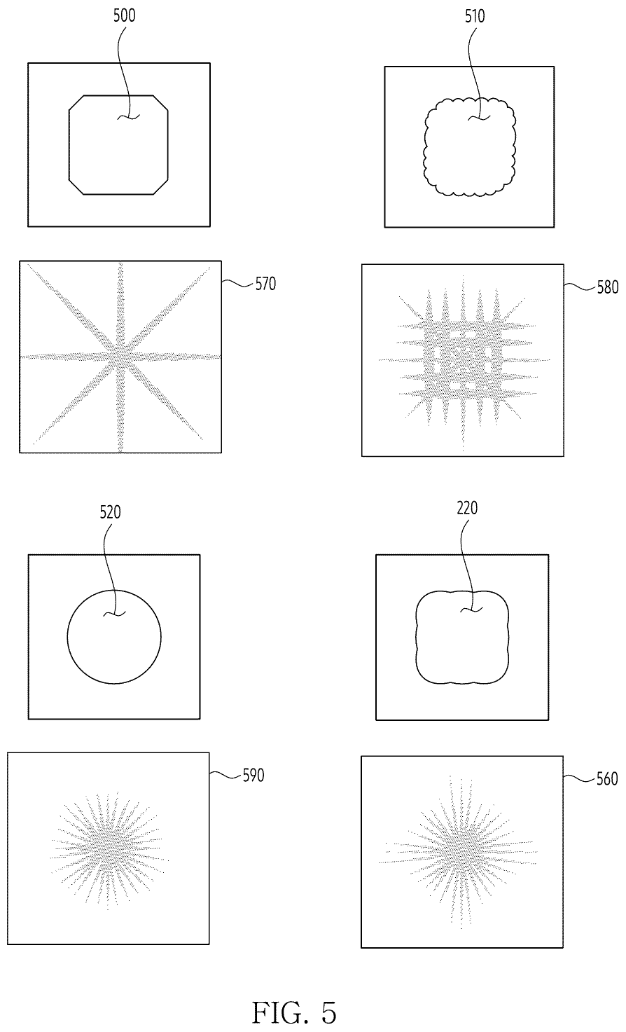

For example, each of the plurality of openings 220 including the periphery 240 including the first portions 410 and the second portions 420 may reduce the diffusion or diffraction of light passing through each of the plurality of openings 220. The decrease in the diffusion (or diffraction) of the light may be exemplified through FIG. 5.

FIG. 5 illustrates a state of light passing through an opening in an opaque metal layer according to an embodiment of the disclosure.

Referring to FIG. 5, light passing through each of a plurality of openings 220 including a periphery 240 including a first portions 410 and a second portions 420 may be diffused as shown in a state 560.

For example, light passing through an opening 500 including an octagon-shaped periphery may diffuse as shown in a state 570, and light passing through an opening 510 including a periphery including a plurality of embossments may diffuse as shown in a state 580. For example, a comparison of the state 560 and the state 570 may indicate that a degree of diffusion of light passing through each of the plurality of openings 220 is less than a degree of diffusion of light passing through the opening 500. For example, a comparison of state 560 and state 580 may indicate that a degree of diffusion of light passing through each of the plurality of openings 220 is less than a degree of diffusion of light passing through opening 510. For example, each of the plurality of openings 220 may reduce diffusion of light than the opening 500 and the opening 510.

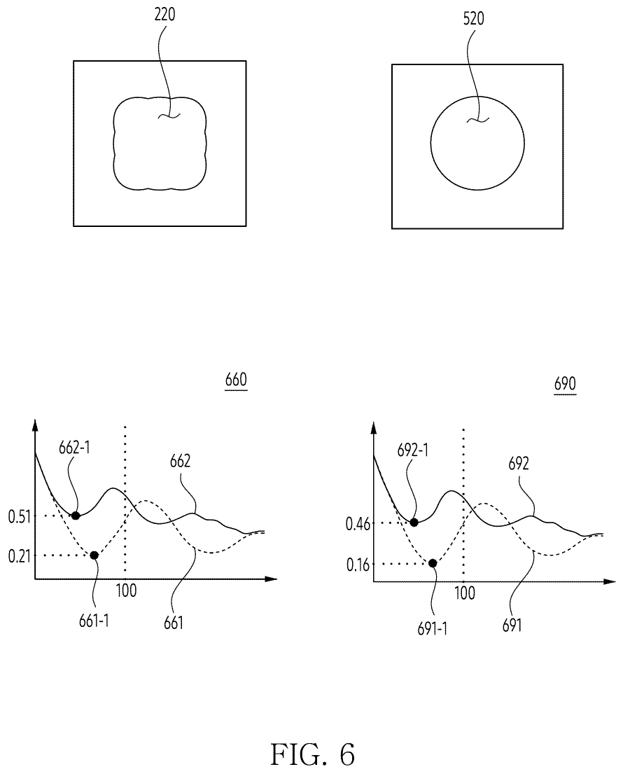

For example, light passing through an opening 520 including a circular-shaped periphery may be diffused as shown in a state 590. For example, a comparison of the state 560 and state 590 may indicate that a degree of diffusion of light passing through each of the plurality of openings 220 is greater than a degree of diffusion of light passing through the opening 520. For example, although the opening 520 reduces the diffusion of light than each of the plurality of openings 220, since a size of the opening 520 is smaller than a size of each of the plurality of openings 220, resolution of an image obtained through the camera 150 based on light passing through the opening 520 may be lower than resolution of an image obtained through the camera 150 based on light passing through each of the plurality of openings 220. A difference between the resolution of the image obtained based on light passing through the opening 520 and the resolution of the image obtained based on the light passing through each of the plurality of openings 220 may be exemplified through FIG. 6.

FIG. 6 illustrates a quality of an image obtained through a camera positioned below an opaque metal layer according to an embodiment of the disclosure.

Referring to FIG. 6, a horizontal axis of each of a chart 660 and a chart 690 indicates the number of real pairs of black line and white line included in 1 millimeter (mm). For example, a vertical axis of each of the chart 660 and the chart 690 indicates resolution of an image for the real pairs. For example, the vertical axis of each of the chart 660 and the chart 690 indicates a difference between a shape of each of the real pairs and a shape of each of visual objects in the image each corresponding to the real pairs.

For example, a line 661 and a line 662 in the chart 660 may indicate resolution (e.g., modulation transfer function (MTF)) of an image obtained based on light passing through each of the plurality of openings 220. For example, the line 661 indicates resolution of an image for a horizontal component (or vertical component) of light. For example, the line 662 indicates resolution of an image for a component of light, inclined 45 degrees with respect to the horizontal component (or vertical component). For example, a minimum value 661-1 of the line 661 in a range where the number of the real pairs is greater than or equal to 0 and less than or equal to 100 may be 0.21, and a minimum value 662-1 of the line 662 in a range where the number of the real pairs is greater than or equal to 0 and less than or equal to 100 may be 0.51.

For example, a line 691 and a line 692 in the chart 690 may indicate resolution (e.g., MTF) of an image obtained based on light passing through the opening 520. For example, the line 691 indicates resolution of an image for a horizontal component (or vertical component) of light. For example, the line 692 indicates resolution of an image for a component of light, inclined 45 degrees with respect to the horizontal component (or vertical component). For example, a minimum value 691-1 of the line 691 in a range where the number of the real pairs is greater than or equal to 0 and less than or equal to 100 may be 0.16 that is lower than the minimum value 661-1 of the line 661, and a minimum value 692-1 of the line 692 in a range where the number of the real pairs is greater than or equal to 0 and less than or equal to 100 may be 0.46 that is lower than the minimum value 662-1 of the line 662. For example, a comparison of the chart 660 including the line 661 and the line 662 with the chart 690 including the line 691 and the line 692 may indicate that a quality of an image obtained based on light passing through each of the openings 220 is higher than a quality of an image obtained based on light passing through the opening 520.

As described above, the opaque metal layer 210 including the plurality of openings 220 including respectively the periphery 240 including the first portions 410 and the second portions 420 may enhance a quality of an image obtained through the camera 150 positioned below the first region 111.

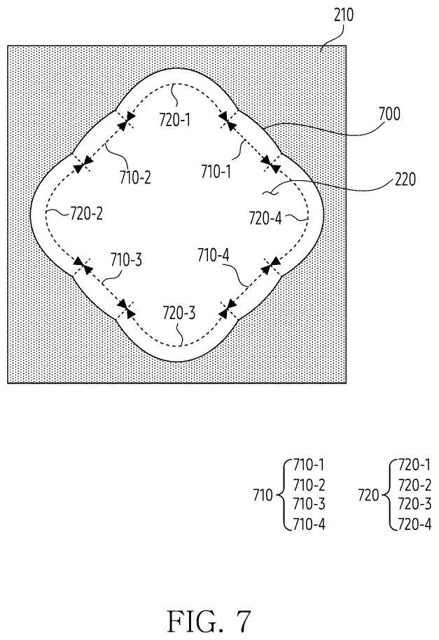

The periphery 240 in each of the plurality of openings 220 may have another shape distinguished from the above-described shape. The other shape may be exemplified through FIG. 7.

FIG. 7 illustrates another example of an opaque metal layer in an display panel according to an embodiment of the disclosure.

Referring to FIG. 7, each of a plurality of openings 220 in an opaque metal layer 210 may include a periphery 700.

For example, the periphery 700 may include first portions 710 having a first radius of curvature. For example, the first portions 710 may include a portion 710-1, a portion 710-2, a portion 710-3, and a portion 710-4. For example, the first portions 710 may be spaced apart from each other. For example, the portion 710-1 may be spaced apart from each of the portion 710-2, the portion 710-3, and the portion 710-4. For example, the portion 710-2 may be spaced apart from each of the portion 710-3 and the portion 710-4. For example, the portion 710-3 may be spaced apart from the portion 710-4.

For example, the periphery 700 may include second portions 720 having a second radius of curvature smaller than the first radius of curvature. For example, the second portions 720 may include a portion 720-1, a portion 720-2, a portion 720-3, and a portion 720-4. For example, the second portions 720 may be spaced apart from each other. For example, the portion 720-1 may be spaced apart from each of the portion 720-2, the portion 720-3, and the portion 720-4. For example, the portion 720-2 may be spaced apart from each of the portion 720-3 and the portion 720-4. For example, the portion 720-3 may be spaced apart from the portion 720-4.

For example, each of the second portions 720 may be positioned between the first portions 710. For example, the portion 720-1 may be positioned between the portion 710-1 and the portion 710-2. For example, the portion 720-1 may connect the portion 710-1 and the portion 710-2. For example, the portion 720-2 may be positioned between the portion 710-2 and the portion 710-3. For example, the portion 720-2 may connect the portion 710-2 and the portion 710-3. For example, the portion 720-3 may be positioned between the portion 710-3 and the portion 710-4. For example, the portion 720-3 may connect the portion 710-3 and the portion 710-4. For example, the portion 720-4 may be positioned between the portion 710-1 and the portion 710-4. For example, the portion 720-4 may connect the portion 710-1 and the portion 710-4.

For example, unlike the first portions 710, the second portions 720 may face each of pixels positioned along the periphery 700. For example, unlike the periphery 240 including the first portions 410 facing the pixels positioned along the periphery 240, the periphery 700 may include the second portions 720 facing respectively the pixels along the periphery 700.

For example, the first portions 710 may be a portion of a circle. For example, a portion (e.g., portion 720-1 and portion 720-3) of the second portions 720 may be a portion of an ellipse. For example, a remaining (or another) portion (e.g., portion 720-2 and portion 720-4) of the second portions 720 may be a portion of another ellipse. For example, a major axis of the ellipse and a major axis of the other ellipse may intersect with each other. For example, the major axis of the ellipse and the major axis of the other ellipse may be substantially perpendicular.

For example, the periphery 700 may include a portion of the circle that is the first portions 710, a portion of the ellipse that is the portion of the second portions 720, and a portion of the other ellipse that is the remaining portion of the second portions 720.

FIG. 8 is a block diagram illustrating an electronic device 801 in a network environment 800 according to an embodiment of the disclosure.

Referring to FIG. 8, the electronic device 801 in the network environment 800 may communicate with an electronic device 802 via a first network 898 (e.g., a short-range wireless communication network), or at least one of an electronic device 804 or a server 808 via a second network 899 (e.g., a long-range wireless communication network). According to an embodiment, the electronic device 801 may communicate with the electronic device 804 via the server 808. According to an embodiment, the electronic device 801 may include a processor 820, memory 830, an input module 850, a sound output module 855, a display module 860, an audio module 870, a sensor module 876, an interface 877, a connecting terminal 878, a haptic module 879, a camera module 880, a power management module 888, a battery 889, a communication module 890, a subscriber identification module (SIM) 896, or an antenna module 897. In some embodiments, at least one of the components (e.g., the connecting terminal 878) may be omitted from the electronic device 801, or one or more other components may be added in the electronic device 801. In some embodiments, some of the components (e.g., the sensor module 876, the camera module 880, or the antenna module 897) may be implemented as a single component (e.g., the display module 860).

The processor 820 may execute, for example, software (e.g., a program 840) to control at least one other component (e.g., a hardware or software component) of the electronic device 801 coupled with the processor 820, and may perform various data processing or computation. According to an embodiment, as at least part of the data processing or computation, the processor 820 may store a command or data received from another component (e.g., the sensor module 876 or the communication module 890) in volatile memory 832, process the command or the data stored in the volatile memory 832, and store resulting data in non-volatile memory 834. According to an embodiment, the processor 820 may include a main processor 821 (e.g., a central processing unit (CPU) or an application processor (AP)), or an auxiliary processor 823 (e.g., a graphics processing unit (GPU), a neural processing unit (NPU), an image signal processor (ISP), a sensor hub processor, or a communication processor (CP)) that is operable independently from, or in conjunction with, the main processor 821. For example, when the electronic device 801 includes the main processor 821 and the auxiliary processor 823, the auxiliary processor 823 may be adapted to consume less power than the main processor 821, or to be specific to a specified function. The auxiliary processor 823 may be implemented as separate from, or as part of the main processor 821.

The auxiliary processor 823 may control at least some of functions or states related to at least one component (e.g., the display module 860, the sensor module 876, or the communication module 890) among the components of the electronic device 801, instead of the main processor 821 while the main processor 821 is in an inactive (e.g., sleep) state, or together with the main processor 821 while the main processor 821 is in an active state (e.g., executing an application). According to an embodiment, the auxiliary processor 823 (e.g., an image signal processor or a communication processor) may be implemented as part of another component (e.g., the camera module 880 or the communication module 890) functionally related to the auxiliary processor 823. According to an embodiment, the auxiliary processor 823 (e.g., the neural processing unit) may include a hardware structure specified for artificial intelligence model processing. An artificial intelligence model may be generated by machine learning. Such learning may be performed, e.g., by the electronic device 801 where the artificial intelligence is performed or via a separate server (e.g., the server 808). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 830 may store various data used by at least one component (e.g., the processor 820 or the sensor module 876) of the electronic device 801. The various data may include, for example, software (e.g., the program 840) and input data or output data for a command related thereto. The memory 830 may include the volatile memory 832 or the non-volatile memory 834.

The program 840 may be stored in the memory 830 as software, and may include, for example, an operating system (OS) 842, middleware 844, or an application 846.

The input module 850 may receive a command or data to be used by another component (e.g., the processor 820) of the electronic device 801, from the outside (e.g., a user) of the electronic device 801. The input module 850 may include, for example, a microphone, a mouse, a keyboard, a key (e.g., a button), or a digital pen (e.g., a stylus pen).

The sound output module 855 may output sound signals to the outside of the electronic device 801. The sound output module 855 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 860 may visually provide information to the outside (e.g., a user) of the electronic device 801. The display module 860 may include, for example, a display, a hologram device, or a projector and control circuitry to control a corresponding one of the display, hologram device, and projector. According to an embodiment, the display module 860 may include a touch sensor adapted to detect a touch, or a pressure sensor adapted to measure the intensity of force incurred by the touch.

The audio module 870 may convert a sound into an electrical signal and vice versa. According to an embodiment, the audio module 870 may obtain the sound via the input module 850, or output the sound via the sound output module 855 or a headphone of an external electronic device (e.g., an electronic device 802) directly (e.g., wiredly) or wirelessly coupled with the electronic device 801.

The sensor module 876 may detect an operational state (e.g., power or temperature) of the electronic device 801 or an environmental state (e.g., a state of a user) external to the electronic device 801, and then generate an electrical signal or data value corresponding to the detected state. According to an embodiment, the sensor module 876 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 877 may support one or more specified protocols to be used for the electronic device 801 to be coupled with the external electronic device (e.g., the electronic device 802) directly (e.g., wiredly) or wirelessly. According to an embodiment, the interface 877 may include, for example, a high definition multimedia interface (HDMI), a universal serial bus (USB) interface, a secure digital (SD) card interface, or an audio interface.

A connecting terminal 878 may include a connector via which the electronic device 801 may be physically connected with the external electronic device (e.g., the electronic device 802). According to an embodiment, the connecting terminal 878 may include, for example, an HDMI connector, a USB connector, a SD card connector, or an audio connector (e.g., a headphone connector).

The haptic module 879 may convert an electrical signal into a mechanical stimulus (e.g., a vibration or a movement) or electrical stimulus which may be recognized by a user via his tactile sensation or kinesthetic sensation. According to an embodiment, the haptic module 879 may include, for example, a motor, a piezoelectric element, or an electric stimulator.

The camera module 880 may capture a still image or moving images. According to an embodiment, the camera module 880 may include one or more lenses, image sensors, image signal processors, or flashes.

The power management module 888 may manage power supplied to the electronic device 801. According to an embodiment, the power management module 888 may be implemented as at least part of, for example, a power management integrated circuit (PMIC).

The battery 889 may supply power to at least one component of the electronic device 801. According to an embodiment, the battery 889 may include, for example, a primary cell which is not rechargeable, a secondary cell which is rechargeable, or a fuel cell.

The communication module 890 may support establishing a direct (e.g., wired) communication channel or a wireless communication channel between the electronic device 801 and the external electronic device (e.g., the electronic device 802, the electronic device 804, or the server 808) and performing communication via the established communication channel. The communication module 890 may include one or more communication processors that are operable independently from the processor 820 (e.g., the application processor (AP)) and supports a direct (e.g., wired) communication or a wireless communication. According to an embodiment, the communication module 890 may include a wireless communication module 892 (e.g., a cellular communication module, a short-range wireless communication module, or a global navigation satellite system (GNSS) communication module) or a wired communication module 894 (e.g., a local area network (LAN) communication module or a power line communication (PLC) module). A corresponding one of these communication modules may communicate with the external electronic device via the first network 898 (e.g., a short-range communication network, such as Bluetooth™, wireless-fidelity (Wi-Fi) direct, or infrared data association (IrDA)) or the second network 899 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 892 may identify and authenticate the electronic device 801 in a communication network, such as the first network 898 or the second network 899, using subscriber information (e.g., international mobile subscriber identity (IMSI)) stored in the subscriber identification module 896.

The wireless communication module 892 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 892 may support a high-frequency band (e.g., the millimeter wave (mmWave) band) to achieve, e.g., a high data transmission rate. The wireless communication module 892 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 892 may support various requirements specified in the electronic device 801, an external electronic device (e.g., the electronic device 804), or a network system (e.g., the second network 899). According to an embodiment, the wireless communication module 892 may support a peak data rate (e.g., 20 Gbps or more) for implementing eMBB, loss coverage (e.g., 864 dB or less) for implementing mMTC, or U-plane latency (e.g., 0.5 ms or less for each of downlink (DL) and uplink (UL), or a round trip of 8 ms or less) for implementing URLLC.

The antenna module 897 may transmit or receive a signal or power to or from the outside (e.g., the external electronic device) of the electronic device 801. According to an embodiment, the antenna module 897 may include an antenna including a radiating element composed of a conductive material or a conductive pattern formed in or on a substrate (e.g., a printed circuit board (PCB)). According to an embodiment, the antenna module 897 may include a plurality of antennas (e.g., array antennas). In such a case, at least one antenna appropriate for a communication scheme used in the communication network, such as the first network 898 or the second network 899, may be selected, for example, by the communication module 890 (e.g., the wireless communication module 892) from the plurality of antennas. The signal or the power may then be transmitted or received between the communication module 890 and the external electronic device via the selected at least one antenna. According to an embodiment, another component (e.g., a radio frequency integrated circuit (RFIC)) other than the radiating element may be additionally formed as part of the antenna module 897.

According to various embodiments, the antenna module 897 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 801 and the external electronic device 804 via the server 808 coupled with the second network 899. Each of the electronic devices 802 or 804 may be a device of a same type as, or a different type, from the electronic device 801. According to an embodiment, all or some of operations to be executed at the electronic device 801 may be executed at one or more of the external electronic devices 802, 804, or 808. For example, if the electronic device 801 should perform a function or a service automatically, or in response to a request from a user or another device, the electronic device 801, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 801. The electronic device 801 may provide the outcome, with or without further processing of the outcome, as at least part of a reply to the request. To that end, a cloud computing, distributed computing, mobile edge computing (MEC), or client-server computing technology may be used, for example. The electronic device 801 may provide ultra low-latency services using, e.g., distributed computing or mobile edge computing. In another embodiment, the external electronic device 804 may include an internet-of-things (IoT) device. The server 808 may be an intelligent server using machine learning and/or a neural network. According to an embodiment, the external electronic device 804 or the server 808 may be included in the second network 899. The electronic device 801 may be applied to intelligent services (e.g., smart home, smart city, smart car, or healthcare) based on 5G communication technology or IoT-related technology.

FIG. 9 is a block diagram 900 illustrating the display module 860 according to an embodiment of the disclosure.

Referring to FIG. 9, the display module 860 may include a display 910 and a display driver integrated circuit (DDI) 930 to control the display 910. The DDI 930 may include an interface module 931, memory 933 (e.g., buffer memory), an image processing module 935, or a mapping module 937. The DDI 930 may receive image information that contains image data or an image control signal corresponding to a command to control the image data from another component of the electronic device 801 via the interface module 931. For example, according to an embodiment, the image information may be received from the processor 820 (e.g., the main processor 821 (e.g., an application processor)) or the auxiliary processor 823 (e.g., a graphics processing unit) operated independently from the function of the main processor 821. The DDI 930 may communicate, for example, with touch circuitry 950 or the sensor module 876 via the interface module 931. The DDI 930 may also store at least part of the received image information in the memory 933, for example, on a frame by frame basis. The image processing module 935 may perform pre-processing or post-processing (e.g., adjustment of resolution, brightness, or size) with respect to at least part of the image data. According to an embodiment, the pre-processing or post-processing may be performed, for example, based at least in part on one or more characteristics of the image data or one or more characteristics of the display 910. The mapping module 937 may generate a voltage value or a current value corresponding to the image data pre-processed or post-processed by the image processing module 935. According to an embodiment, the generating of the voltage value or current value may be performed, for example, based at least in part on one or more attributes of the pixels (e.g., an array, such as an RGB stripe or a pentile structure, of the pixels, or the size of each subpixel). At least some pixels of the display 910 may be driven, for example, based at least in part on the voltage value or the current value such that visual information (e.g., a text, an image, or an icon) corresponding to the image data may be displayed via the display 910.

According to an embodiment, the display module 860 may further include the touch circuitry 950. The touch circuitry 950 may include a touch sensor 951 and a touch sensor IC 953 to control the touch sensor 951. The touch sensor IC 953 may control the touch sensor 951 to sense a touch input or a hovering input with respect to a certain position on the display 910. To achieve this, for example, the touch sensor 951 may detect (e.g., measure) a change in a signal (e.g., a voltage, a quantity of light, a resistance, or a quantity of one or more electric charges) corresponding to the certain position on the display 910. The touch circuitry 950 may provide input information (e.g., a position, an area, a pressure, or a time) indicative of the touch input or the hovering input detected via the touch sensor 951 to the processor 820. According to an embodiment, at least part (e.g., the touch sensor IC 953) of the touch circuitry 950 may be formed as part of the display 910 or the DDI 930, or as part of another component (e.g., the auxiliary processor 823) disposed outside the display module 860.

According to an embodiment, the display module 860 may further include at least one sensor (e.g., a fingerprint sensor, an iris sensor, a pressure sensor, or an illuminance sensor) of the sensor module 876 or a control circuit for the at least one sensor. In such a case, the at least one sensor or the control circuit for the at least one sensor may be embedded in one portion of a component (e.g., the display 910, the DDI 930, or the touch circuitry 950)) of the display module 860. For example, when the sensor module 876 embedded in the display module 860 includes a biometric sensor (e.g., a fingerprint sensor), the biometric sensor may obtain biometric information (e.g., a fingerprint image) corresponding to a touch input received via a portion of the display 910. As another example, when the sensor module 876 embedded in the display module 860 includes a pressure sensor, the pressure sensor may obtain pressure information corresponding to a touch input received via a partial or whole area of the display 910. According to an embodiment, the touch sensor 951 or the sensor module 876 may be disposed between pixels in a pixel layer of the display 910, or over or under the pixel layer.

As described above, an electronic device 100 may comprise a camera 150. The electronic device 100 may comprise a display panel 110 including a first region 111 disposed on the camera 150, and a second region 112 surrounding at least portion of the first region 111. According to an embodiment, the first region 111 may include an emission layer 300 including a plurality of pixels 200 uniformly spaced apart from each other, an encapsulation layer 310 on the emission layer 300, and an opaque metal layer 210 below the emission layer 300. According to an embodiment, the opaque metal layer 210 may include a plurality of openings 220 disposed between the plurality of pixels 200 when viewing the first region 111 in a first direction opposite to a second direction in which the display panel 110 faces. According to an embodiment, each of the plurality of openings 220 may include a periphery 240 including, when viewing the first region 111 in the first direction, first portions 410, each having a first radius of curvature, spaced apart from each other, and second portions 420, each having a second radius of curvature shorter than the first radius of curvature, positioned between the first portions 410 of the periphery 240. According to an embodiment, each of the first portions 410 may face each of pixels 200-3, 200-4, 200-5, and 200-6 positioned along the periphery 240.

According to an embodiment, the first portions 410 may be part of a circle 470.

According to an embodiment, portion 420-1 and 420-3 of the second portions may be part of an ellipse 480. According to an embodiment, remaining portion 420-2 and 420-4 of the second portions may be part of another ellipse 490.

According to an embodiment, a major axis of the ellipse 480 may be perpendicular to a major axis of the another ellipse 490.

According to an embodiment, the pixels 200-3, 200-4, 200-5, and 200-6 may include first pixels 200-4 and 200-6 on the same row, and second pixels 200-3 and 200-5 on the same column. According to an embodiment, a center of the circle 470 may be positioned at an intersection point 450 of a first line 440-1 connecting points 430-2 and 430-4 indicating positions of the first pixels 200-4 and 200-6 and a second line 440-2 connecting points 430-1 and 430-3 indicating positions of the second pixel 200-3 and 200-5.

According to an embodiment, the second region 112 may include the emission layer including a plurality of other pixels uniformly spaced apart from each other and the encapsulation layer. According to an embodiment, a spacing between the plurality of other pixels may be narrower than a spacing between the plurality of pixels 200.

According to an embodiment, the emission layer 300 may include a substrate 330 including a thin film transistor (TFT) 320. According to an embodiment, the emission layer 300 may include a second layer 340 on substrate 330 including a first electrode. According to an embodiment, the emission layer 300 may include a third layer 350 on the second layer 340 including an organic emitting material. According to an embodiment, the emission layer 300 may include a fourth layer 360 on the third layer 350, including a second electrode, contacted with the encapsulation layer 310.

According to an embodiment, the number of the first portions 410 may be 4. According to an embodiment, the number of the second portions 420 may be 4.

According to an embodiment, the first portions 410 may include a third portion 410-1, a fourth portion 410-3, spaced apart from the third portion 410-1, facing the third portion 410-1, a fifth portion 410-2, and a sixth portion 410-4, spaced apart from the fifth portion 410-2, facing the fifth portion 410-2. According to an embodiment, the second portions 420 may include a seventh portion 420-1, an eighth portion 420-3, spaced apart from the seventh portion 420-1, facing the seventh portion 420-1, a ninth portion 420-2, and a tenth portion 420-4, spaced apart from the ninth portion 420-2, facing the ninth portion 420-2.

According to an embodiment, the opaque metal layer 210 may be positioned below the emission layer 300 to reduce diffraction of light being caused by the plurality of pixels 200 and a plurality of electrical wires for driving the plurality of pixels 200.

As described above, a display panel 110 may comprise a first region 111 disposed on a camera 150, and a second region 112 surrounding at least portion of the first region 111. According to an embodiment, the first region 111 may include an emission layer 300 including a plurality of pixels 200 uniformly spaced apart from each other, an encapsulation layer 310 on the emission layer 300, and an opaque metal layer 210 below the emission layer 300. According to an embodiment, the opaque metal layer 210 may include a plurality of openings 220 disposed between the plurality of pixels 200 when viewing the first region 111 in a first direction opposite to a second direction in which the display panel 110 faces. According to an embodiment, each of the plurality of openings 220 may include a periphery 240 including, when viewing the first region 111 in the first direction, first portions 410, each having a first radius of curvature, spaced apart from each other, and second portions 420, each having a second radius of curvature shorter than the first radius of curvature, positioned between the first portions 410 of the periphery 240. According to an embodiment, each of the first portions 410 may face each of pixels 200-3, 200-4, 200-5, and 200-6 positioned along the periphery 240.

According to an embodiment, the first portions 410 of the periphery 240 may be part of a circle 470.

According to an embodiment, portion 420-1 and 420-3 of the second portions may be part of an ellipse 480. According to an embodiment, remaining portion 420-2 and 420-4 of the second portions may be part of another ellipse 490.

According to an embodiment, a major axis of the ellipse 480 may be perpendicular to a major axis of the another ellipse 490.

According to an embodiment, the pixels 200-3, 200-4, 200-5, and 200-6 may include first pixels 200-4 and 200-6 on the same row, and second pixels 200-3 and 200-5 on the same column. According to an embodiment, a center of the circle 470 may be positioned at an intersection point 450 of a first line 440-1 connecting points 430-2 and 430-4 indicating positions of the first pixels 200-4 and 200-6 and a second line 440-2 connecting points 430-1 and 430-3 indicating positions of the second pixel 200-3 and 200-5.

According to an embodiment, the second region 112 may include the emission layer including a plurality of other pixels uniformly spaced apart from each other and the encapsulation layer. According to an embodiment, a spacing between the plurality of other pixels may be narrower than a spacing between the plurality of pixels 200.

According to an embodiment, the emission layer 300 may include a substrate 330 including a thin film transistor (TFT) 320. According to an embodiment, the emission layer 300 may include a second layer 340 on substrate 330 including a first electrode. According to an embodiment, the emission layer 300 may include a third layer 350 on the second layer 340 including an organic emitting material. According to an embodiment, the emission layer 300 may include a fourth layer 360 on the third layer 350, including a second electrode, contacted with the encapsulation layer 310.

According to an embodiment, the number of the first portions 410 may be 4. According to an embodiment, the number of the second portions 420 may be 4.

According to an embodiment, the first portions 410 may include a third portion 410-1, a fourth portion 410-3, spaced apart from the third portion 410-1, facing the third portion 410-1, a fifth portion 410-2, and a sixth portion 410-4, spaced apart from the fifth portion 410-2, facing the fifth portion 410-2. According to an embodiment, the second portions 420 may include a seventh portion 420-1, an eighth portion 420-3, spaced apart from the seventh portion 420-1, facing the seventh portion 420-1, a ninth portion 420-2, and a tenth portion 420-4, spaced apart from the ninth portion 420-2, facing the ninth portion 420-2.

According to an embodiment, the opaque metal layer 210 may be positioned below the emission layer 300 to reduce diffraction of light being caused by the plurality of pixels 200 and a plurality of electrical wires for driving the plurality of pixels 200.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 840) including one or more instructions that are stored in a storage medium (e.g., internal memory 836 or external memory 838) that is readable by a machine (e.g., the electronic device 801). For example, a processor (e.g., the processor 820) of the machine (e.g., the electronic device 801) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a camera; and
a display panel including:
a first region disposed on the camera, and
a second region surrounding at least portion of the first region,
wherein the first region includes:
an emission layer including a plurality of pixels uniformly spaced apart from each other,
an encapsulation layer on the emission layer, and
an opaque metal layer below the emission layer,
wherein the opaque metal layer includes a plurality of openings disposed between the plurality of pixels,
wherein each of the plurality of openings includes a periphery including:
first portions, each having a first radius of curvature, spaced apart from each other, and
second portions, each having a second radius of curvature shorter than the first radius of curvature, positioned between the first portions of the periphery, and
wherein each of the first portions of the periphery faces each of pixels positioned along the periphery.

2. The electronic device of claim 1, wherein the first portions of the periphery are part of a circle.

3. The electronic device of claim 2,
wherein a portion of the second portions of the periphery forms part of an ellipse, and
wherein remaining portion of the second portions of the periphery is part of another ellipse.

4. The electronic device of claim 3, wherein a major axis of the ellipse is perpendicular to a major axis of the other ellipse.

5. The electronic device of claim 2,
wherein the pixels include first pixels on a same row, and second pixels on a same column, and
wherein the center of the circle is positioned at an intersection point of a first line connecting points indicating positions of the first pixels and a second line connecting points indicating positions of the second pixel.

6. The electronic device of claim 1,
wherein the second region includes the emission layer including a plurality of other pixels uniformly spaced apart from each other and the encapsulation layer, and
wherein a spacing between the plurality of other pixels is narrower than a spacing between the plurality of pixels.

7. The electronic device of claim 1, wherein the emission layer includes:
a circuit layer including a thin film transistor (TFT),
a second layer on the circuit layer including a first electrode,
a third layer on the second layer including an organic emitting material, and
a fourth layer on the third layer, including a second electrode, contacted with the encapsulation layer.

8. The electronic device of claim 1, wherein the periphery includes four first portions and four second portions.

9. The electronic device of claim 8,
wherein the first portions of the periphery includes:
a third portion,
a fourth portion, spaced apart from the third portion, facing the third portion,
a fifth portion, and
a sixth portion, spaced apart from the fifth portion, facing the fifth portion, and
wherein the second portions of the periphery includes:
a seventh portion,
an eighth portion, spaced apart from the seventh portion, facing the seventh portion,
a ninth portion, and
a tenth portion, spaced apart from the ninth portion, facing the ninth portion.

10. The electronic device of claim 1, wherein the opaque metal layer is positioned below the emission layer to reduce diffraction of light being caused by the plurality of pixels and a plurality of electrical wires for driving the plurality of pixels.

11. A display panel comprising:
a first region disposed on a camera, and
a second region surrounding at least portion of the first region,
wherein the first region includes:
an emission layer including a plurality of pixels uniformly spaced apart from each other,
an encapsulation layer on the emission layer, and
an opaque metal layer below the emission layer,
wherein the opaque metal layer includes a plurality of openings disposed between the plurality of pixels,
wherein each of the plurality of openings includes a periphery including:
first portions, each having a first radius of curvature, spaced apart from each other, and
second portions, each having a second radius of curvature shorter than the first radius of curvature, positioned between the first portions of the periphery, and
wherein each of the first portions of the periphery faces each of pixels positioned along the periphery.

12. The display panel of claim 11, wherein the first portions of the periphery are part of a circle.

13. The display panel of claim 12,
wherein a portion of the second portions of the periphery forms part of an ellipse, and
wherein remaining portion of the second portions of the periphery is part of another ellipse.

14. The display panel of claim 13, wherein a major axis of the ellipse is perpendicular to a major axis of the other ellipse.

15. The display panel of claim 12,
wherein the pixels include first pixels on a same row, and second pixels on a same column, and
wherein the center of the circle is positioned at an intersection point of a first line connecting points indicating positions of the first pixels and a second line connecting points indicating positions of the second pixel.

16. The display panel of claim 11,
wherein the second region includes the emission layer including a plurality of other pixels uniformly spaced apart from each other and the encapsulation layer, and
wherein a spacing between the plurality of other pixels is narrower than a spacing between the plurality of pixels.

17. The display panel of claim 11, wherein the emission layer includes:
a circuit layer including a thin film transistor (TFT),
a second layer on the circuit layer including a first electrode,
a third layer on the second layer including an organic emitting material, and
a fourth layer on the third layer, including a second electrode, contacted with the encapsulation layer.

18. The display panel of claim 11, wherein the periphery includes four first portions and four second portions.

19. The display panel of claim 18,
wherein the first portions of the periphery includes:
a third portion,
a fourth portion, spaced apart from the third portion, facing the third portion,
a fifth portion, and
a sixth portion, spaced apart from the fifth portion, facing the fifth portion, and
wherein the second portions of the periphery includes:
a seventh portion,
an eighth portion, spaced apart from the seventh portion, facing the seventh portion,
a ninth portion, and
a tenth portion, spaced apart from the ninth portion, facing the ninth portion.

20. The display panel of claim 11, wherein the opaque metal layer is positioned below the emission layer to reduce diffraction of light being caused by the plurality of pixels and a plurality of electrical wires for driving the plurality of pixels.
